(19) United States
(12) Patent Application Publication
(10) Pub. No.: US 2009/0141461 A1
(43) Pub. Date: Jun. 4, 2009

(54) Circuit board position structure

(75) Inventor: Wen-Hua Chen, Taipei (TW)

Correspondence Address: RABIN & Berdo, PC, 1101 14TH STREET, NW, SUITE 500, WASHINGTON, DC, 20005, US

(73) Assignee: INVENTEC CORPORATION, Taipei (TW)

(21) Appl. No.: 11/998,419

(22) Filed: Nov. 30, 2007

(51) Int. Cl. H05K 5/02

(52) U.S. Cl. 361/752

(57) ABSTRACT

A positioning structure is applied to an electrode device, which includes a movable component and an elastic element. The movable component is moved towards the joining direction for the circuit board and a case to press the elastic element, so as to deform the elastic element. A stopper is against the circuit board to fix the circuit board. Once the being against stopper is released from the circuit board, the elastic element pushes the circuit board along a releasing direction, and thereby the circuit board being conveniently disassembled.

### BACKGROUND OF THE INVENTION

1. Field of the Invention

The present invention relates to a positioning structure. More particularly, the present invention relates to a positioning structure of a circuit board.

2. Related Art

Recently, as the vigorous development of science and technology and information, computer equipment has become a quite popularized electronic device. As for the computer equipments available on the current market, no matter desktop computers, notebooks or servers, a motherboard must be installed therein to serve as a core member for the computer system, such that the central processing unit (CPU), memory module, peripheral controller interface (PCI) card, and other computer peripheral hardware electrically connected onto the motherboard are capable of successively executing preset functions.

As for the common manner of fixing the motherboard, a plurality of conductive copper bosses is disposed on a case of computer device to serve as fixing components, and a plurality of through holes corresponding to the copper bosses is opened on the motherboard. The motherboard is placed on the copper bosses, and keeps a suitable distance from the case. Then, a plurality of bolts is used to pass through the through holes of the motherboard and then screwed on the copper bosses, such that the motherboard generates a suspension effect through using the copper bosses, so as to prevent the weld leg contacts on the back side of the motherboard from directly contacting the case to result in short circuit.

In the conventional manner of screwing and fixing the motherboard through using the copper bosses, during the process of assembling and disassembling the motherboard, the user must repeatedly screw and unscrew the bolts one by one, so it is quite time consuming and complex, which is quite inconvenient in the practical operations. The current electronic devices are required to be light, thin, short, and small, too many copper bosses may occupy too much area on the motherboard, as a result, the circuit layout on the motherboard may become complicated, and the overall electronic device cannot be miniaturized.

Therefore, currently, a thumb screw capable of being turned directly with fingers has been proposed to serve as a positioning component for fixing the motherboard, thereby greatly reducing the number of copper bosses used and thus solving problems generated when screwing and fixing the motherboard through using the copper bosses. Referring to FIG. 1, it is a schematic three-dimensional exploded view of a thumb screw, a circuit board, and a case in the conventional art. A case 10 has a plurality of positioning columns 11 and a screw hole 61, and a neck portion 12 is opened at an upper portion of each positioning column 11. A plurality of positioning holes 21 corresponding to the positioning columns 11 is opened on a circuit board 20. Each positioning hole 21 is cucurbit-shaped and has a wide section 22 and a narrow section 23, and the front end of the positioning column 11 passes through the positioning hole 21 via the wide section 22. In this way, the circuit board 20 can slide on the case 10 through the positioning columns 11, such that the narrow section 23 of the positioning hole 21 is made to be embedded in the neck portion 12 of the positioning column 11. Then, the circuit board 20 can be fixed on the case 10, as long as the thumb screw 60 passes through the circuit board 20 and is screwed into the screw hole 61.

However, the above manner of fixing the motherboard through using the thumb screw still belongs to a screwing manner, the process of assembling and disassembling the motherboard is quite complex, which is not only time-consuming, but the cost of the thumb screws is also higher than the conventional bolts, and as a result, both the material cost and the manpower cost are increased. Therefore, recently, it is an urgent problem to be solved by technicians in the relevant field how to truly confirm the assembling positions of the motherboard when being fixed through a screwless manner, which enables the user to quickly and conveniently assemble and disassemble the motherboard.

### SUMMARY OF THE INVENTION

In view of the above problems, the present invention is directed to a positioning structure to solve the problems in the conventional art when the motherboard is assembled and disassembled through the screwing manner, such as the electronic device cannot be miniaturized, the assembling and disassembling processes are too complex and time consuming, and certain tools are required for unscrewing, the manufacturing cost is too high, and it is inconvenient for the users to operate.

The positioning structure provided by the present invention is applied to an electronic device. The electronic device has a case and a circuit board, the circuit board has at least one joining hole, and the case has at least one joining post corresponding to the joining hole. The joining post is disposed on one side of the case. The circuit board moves towards a joining direction relative to the case and then the circuit board is fixed on the case when the joining hole and the joining post are joined together. Thus, the circuit board is positioned on the case by the positioning structure.

The positioning structure includes a base, a movable component, an elastic element, and a stopper. The base is disposed on the case. The movable component is disposed on the base, and moves relative to the base. The movable component has a sliding block and a pillar, the sliding block slides on the base towards the joining direction, and one end of the pillar is aligned with and corresponds to a through hole of the circuit board. At least one elastic element is disposed between the sliding block and the base. The sliding block slides towards the joining direction, so as to make the elastic element be elastically deformed. The stopper is disposed on the case, for being against one side edge of the circuit board and restricting the movement of the circuit board.

The efficacy of the present invention lies in that, the positioning structure utilizes the matching effect of the base, the movable component, and the elastic element to make the movable component move along the joining direction together with the circuit board and the case to make the elastic element be elastically deformed. The stopper is used to being against the circuit board, so as to enable the circuit board to be stably installed on the case. The stopper is released from the circuit board to make the circuit board automatically move towards a releasing direction under the elastic restoring force of the elastic element, so as to make the circuit board be disassembled from the case. In this way, the user does not need to fix the circuit board through using a plurality of sets of bolts, so as to truly integrate the circuit board on the case through a screwless manner, such that the user can quickly assemble and disassemble the circuit board in a labor-saving way and the operating convenience is greatly improved.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, which thus is not limitative of the present invention, and wherein:

FIG. 1 is a three-dimensional exploded view of a thumb screw, a circuit board, and a case in the conventional art;

FIG. 2 is a schematic three-dimensional exploded view of a first embodiment of the present invention;

FIG. 2A is a schematic three-dimensional exploded view of an embodiment of the present invention;

FIG. 3 is a schematic three-dimensional exploded view of a positioning structure according to a second embodiment of the present invention;

FIG. 3A is a partial cross-sectional enlarged side view of FIG. 3; and

FIGS. 4 to 6 are schematic three-dimensional exploded views of the circuit board installed on the case according to the second embodiment of the present invention.

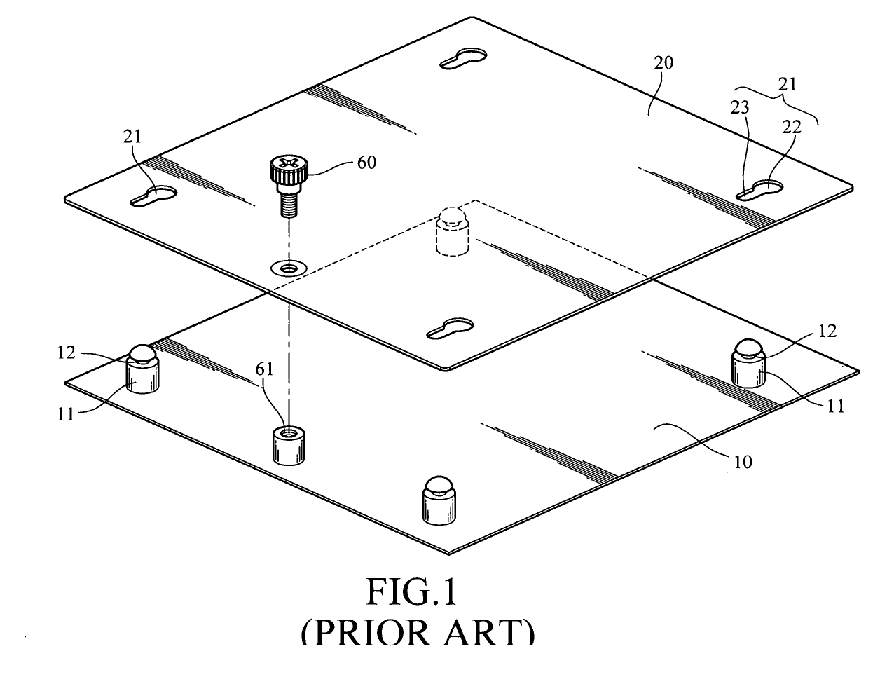

### DETAILED DESCRIPTION OF THE INVENTION

The positioning structure provided by the present invention is applied to the electronic device. The electronic device includes, but not limited to, desktop computers, notebooks, servers, and other computer devices having circuit boards to perform operations. The accompanying drawings of the present invention are merely intended to provide references for demonstrations, but not to limit the present invention.

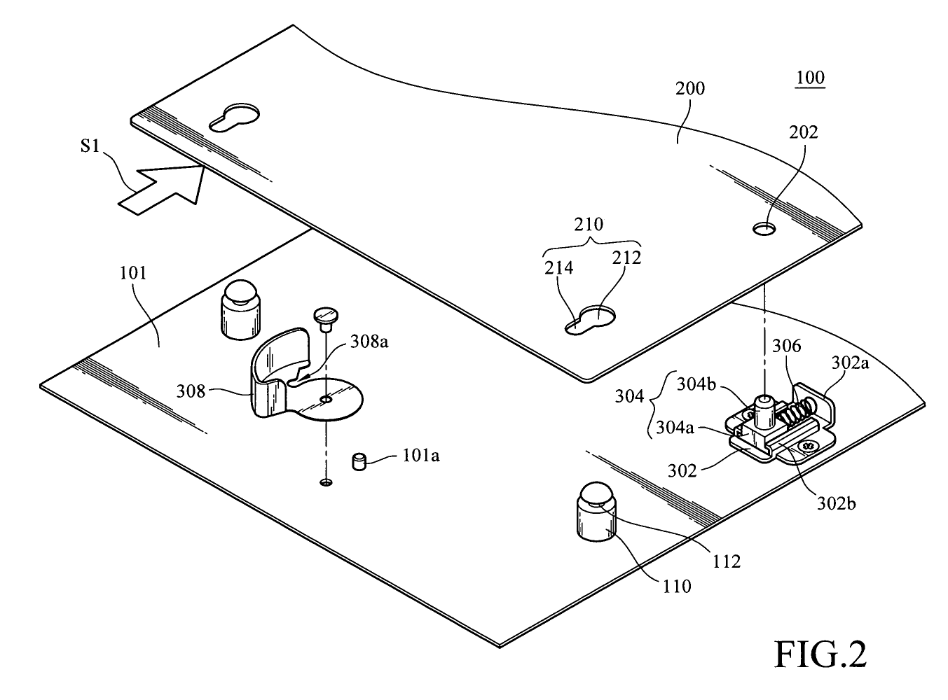

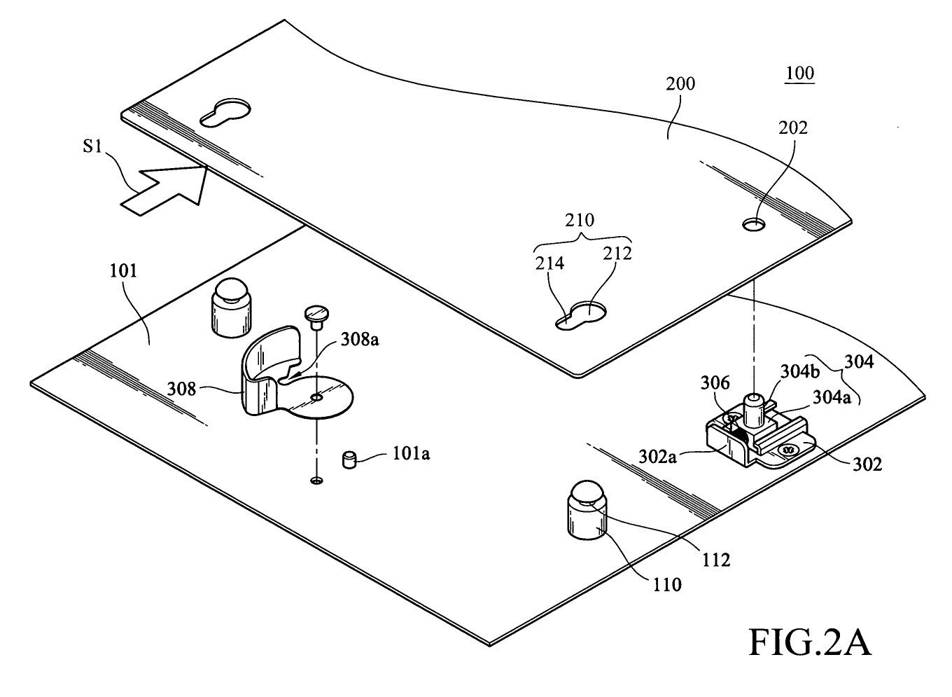

Referring to FIG. 2, it is a schematic three-dimensional exploded view of a first embodiment of the present invention. The positioning structure of the present invention is applied on an electronic device 100. The electronic device 100 has an case 101 and a circuit board 200, at least one joining post 110 is disposed on the case 101, and at least one joining hole 210 is opened on the circuit board 200. A neck portion 112 is opened on the top end of the joining post 110, and the joining hole 210 is a cucurbit-shaped structure formed by a wide section 212 and a narrow section 214 extending from the peripheral edge of the wide section 212, so as to accommodate the neck portion 112 of the joining post 110. With the joining post 110 passing through the wide section 212 of the joining hole 210, the circuit board 200 moves towards a joining direction S1 or a releasing direction S2 relative to the case 101, so as to make the circuit board 200 be positioned or released from the case 101.

Referring to FIG. 2, the positioning structure of the present invention includes a base 302, a movable component 304, an elastic element 306, and a stopper 308. The base 302 is disposed on the case 101, and the base 302 may be an L-shaped base 302 having one side plate 302a, and two guide rails 302b are further disposed on the base 302. The movable component 304 is disposed on the base 302, so as to make the movable component 304 move relative to the base 302. The movable component 304 has a sliding block 304a and a pillar 304b disposed on the sliding block 304a. The sliding block 304a slides along an orbit of the two guide rails 302b on the base 302, and the diameter of the pillar 304b is smaller than the aperture of the through hole 202 of the circuit board 200, so as to make the pillar 304b pass through the through hole 202 of the circuit board 200. The elastic element 306 is disposed between the sliding block 304a and the side plate 302a of the base 302, and when the movable component 304 moves along the joining direction S1 of the circuit board 200, the sliding block 304a makes the elastic element 306 be elastically deformed. The stopper 308 is disposed on the case 101 for being against one side edge of the circuit board 200 and restricting the movement of the circuit board 200. As shown in FIG. 2, the stopper 308 may be a rotating stopper pivoted on the case 101, so as to horizontally rotate with respect to the case 101. A depressed portion 308a of the stopper 308 is snapped with a column body 101a of the case 101, so as to fix the stopper 308 on the case 101.

The elastic element 306 may be a compression spring or an extension spring. In the first embodiment, as shown in FIG. 2, the elastic element 306 is a compression spring. At this time, the elastic element 306 is disposed on a path of the joining direction for the circuit board 200 and the case 101. In other words, when the movable component 304 moves along the joining direction S1 of the circuit board 200, the sliding block 304a compresses the elastic element 306, such that the elastic element 306 is elastically deformed.

Alternatively, the L-shaped base 302 may be disposed to be horizontally rotated for 180° with respect to the L-shaped base 302 of FIG. 2, as shown in FIG. 2A. At this time, the elastic element 306 is an extension spring. That is, the elastic element 306 is disposed on the path of the releasing direction S2 for the circuit board 200 and the case 101. Therefore, when the movable component 304 moves along the joining direction S1, the sliding block 304 makes the elastic element 306 be extended, such that the elastic element 306 is elastically deformed.

In addition, the base 302 may also be a base 302 having two opposite side plates 302a, that is, the base 302 is U-shaped (not shown), or a hollow housing 303 (as the second embodiment described below), but the shape of the base 302 is not used to limit the present invention. When the base 302 is a U-shaped base 302 having two opposite side plates 302a, the movable component 304 moves between the two opposite side plates 302a. The compression spring and the extension spring are respectively disposed on two sides of the sliding block 304a and between two opposite side plates, in which the compression spring is disposed on the joining direction S1 for the circuit board 200 and the case 101, and the extension spring is disposed on the releasing direction S2 for the circuit board 200 and the case 101.

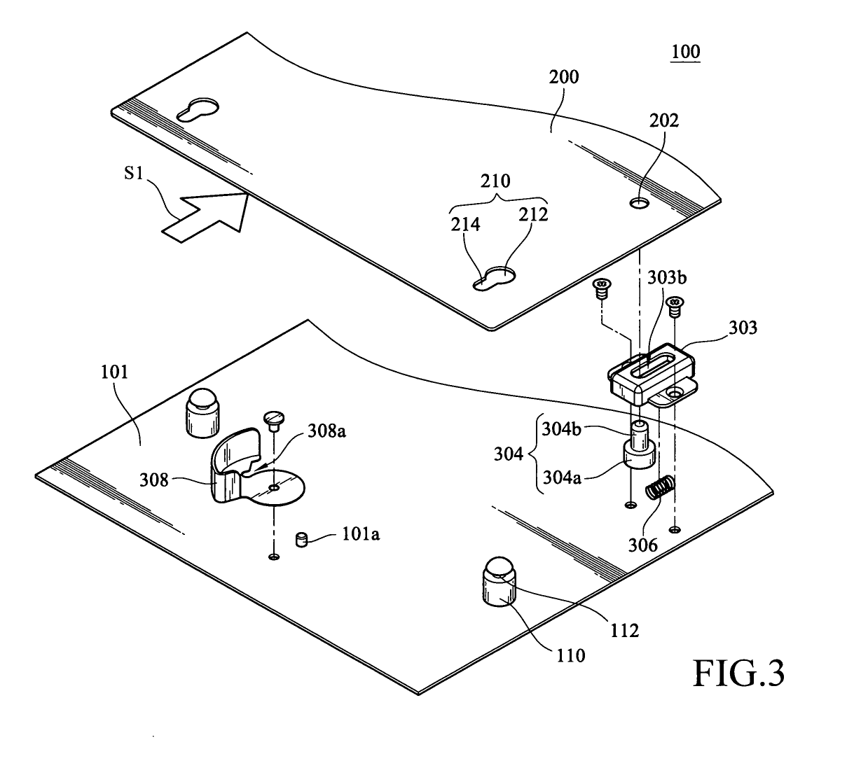

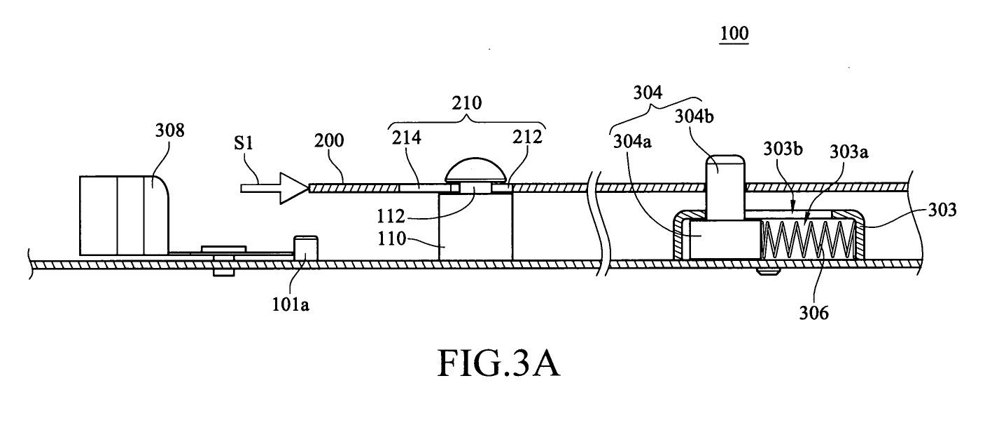

Referring to FIG. 3, it is a schematic three-dimensional exploded view of a positioning structure according to a second embodiment of the present invention. Referring to FIG. 3A, it is a partial cross-sectional enlarged side view of FIG. 3. In this embodiment, the base 302 is, for example, the hollow housing 303. The hollow housing 303 has a chamber 303a and an opening 303b on the upper surface, and the aperture of the opening 303b is greater than the diameter of the pillar 304b of the movable component 304, such that the pillar 304b protrudes out of the opening 303b. The sliding block 304a of the movable component 304 is accommodated within the chamber 303a of the hollow housing 303, and the pillar 304b disposed on the sliding block 304a protrudes out of the opening 303b of the hollow housing 303 and passes through a through hole 202 of the circuit board 200. The elastic element 306 is disposed between the sliding block 304a and the hollow housing 303, and particularly, it is disposed between the sliding block 304a and one side plate 303a of the hollow housing 303. It can be known that, when the movable component 304 moves along the joining direction S1, the sliding block 304a makes the elastic element 306 be elastically deformed.

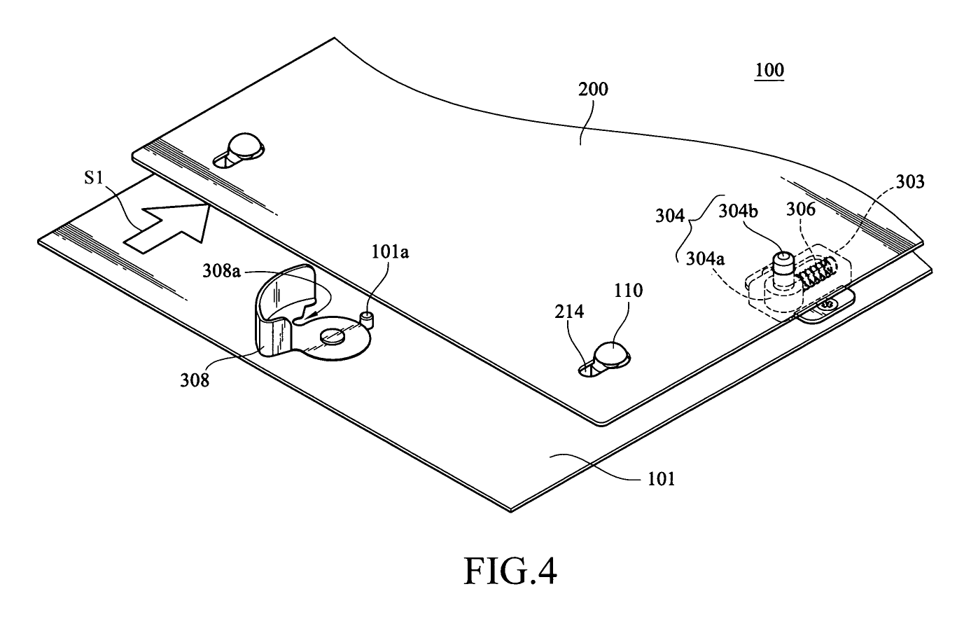

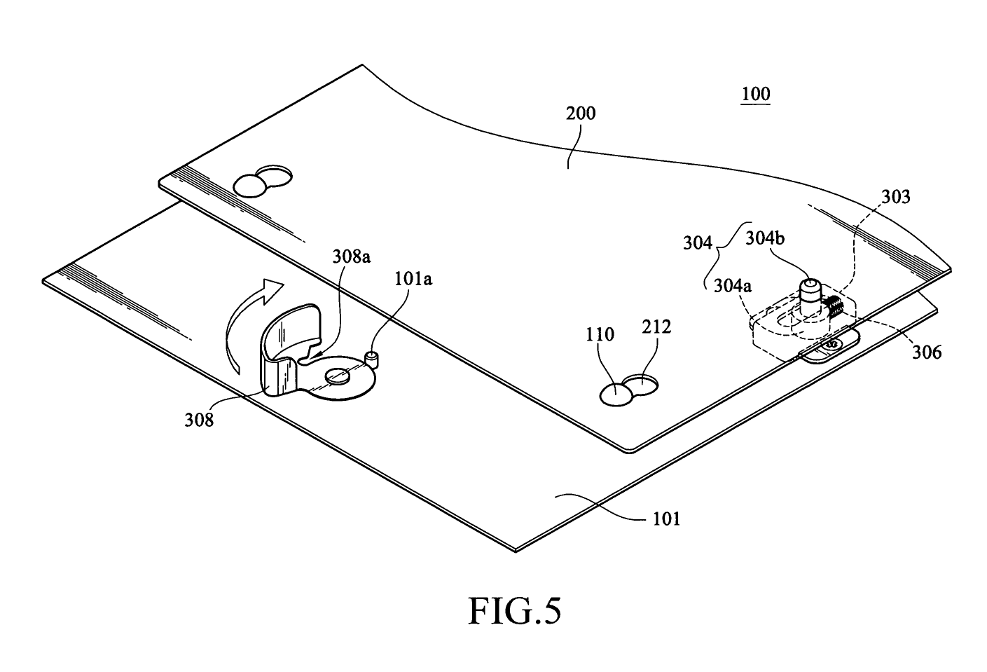

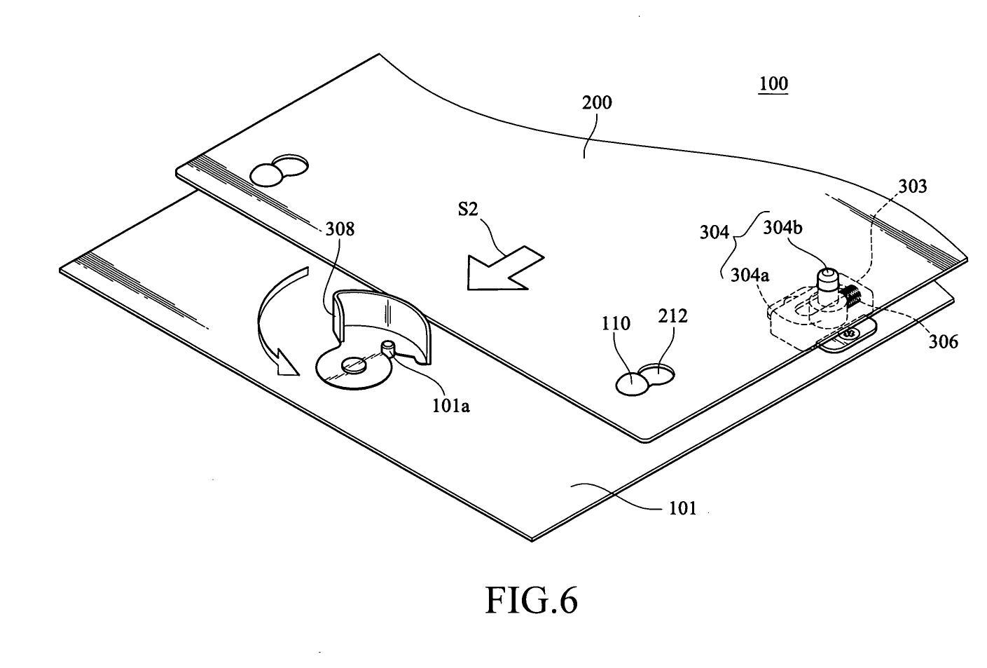

FIGS. 4 to 6 are schematic three-dimensional exploded views of the circuit board installed on the case according to the second embodiment of the present invention. When the circuit board 200 is installed on the case 101, the neck portion 112 of the joining post 110 on the case 101 may be accommodated within the wide section 212 of the joining hole 210. At this time, the pillar 304b of the movable component 304 may be accommodated in the through hole 202 of the circuit board 200. Then, as shown in FIG. 5, the circuit board 200 moves relative to the case 101 along a joining direction, so that the neck portion 112 of the joining post 110 is embedded in the narrow section 214 of the joining hole 210, and they are joined together, thus the circuit board 200 is made to be fixed with the case 101. At this time, the pillar 304b of the movable component 304 is accommodated in the through hole 202 of the circuit board 200. When the circuit board 200 moves relative to the case 101 along the joining direction, the sliding block 304a makes the elastic element 306 be elastically deformed, so as to generate an elastic restoring force. Then, as shown in FIG. 6, the rotating stopper 308 is rotated to being against one side edge of the circuit board 200. In this way, the circuit board 200 is fixed on the case 101.

If it intends to disassemble the circuit board 200 from the case 101, the rotating stopper 308 is rotated in the releasing direction, such that the circuit board 200 is released from the rotating stopper 308. At this time, the elastic restoring force of the elastic element 306 forces the sliding block 304a to move to the initial position, and drives the circuit board 200 to restore to the releasing state shown in FIG. 4. Particularly, once the stopper 308 is released from the circuit board 200, the sliding block 304a is pushed to make a movement under the elastic restoring force of the elastic element 306. At this time, the pillar 304b of the movable component 304 is accommodated in the through hole 202 of the circuit board 200, so the movable component 304 drives the circuit board 200 to move towards the releasing direction S2, and the neck portion 112 of the joining post 110 is made to move into the wide section 212 of the joining hole 210, so as to disassemble the circuit board 200. In this way, the circuit board 200 can be disassembled from the case 101.

The positioning structure provided by the present invention utilizes the matching effect of the base 302, the movable component 304, and the elastic element 306 to make the movable component 304 move together with the circuit board 200 and the case 101 along the joining direction S1 and to make the elastic element 306 be elastically deformed. At this time, the stopper 308 is used to being against the circuit board 200, such that the circuit board is stably installed on the case 101. Once the stopper 308 is released from the circuit board 200, the circuit board 200 automatically moves along a releasing direction under the elastic restoring force of the elastic element 306, such that the circuit board 200 is disassembled from the case 101. In this manner, the user can fix the circuit board without using a plurality of sets of bolts, so as to truly integrate the circuit board on the case through a screwless manner. Thus, the user can quickly assemble and disassemble the circuit board in a labor-saving way and the operating convenience can be greatly improved.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A positioning structure, applied on an electronic device having an case and a circuit board, the circuit board having at least one joining hole, the case having at least one joining post, the circuit board moving towards a joining direction relative to the case so as to fix on the case while the joining hole and the joining post are joined together, the positioning structure comprising:
a base, disposed on the case;
a movable component, disposed on the base, having a sliding block and a pillar, the sliding block sliding on the base towards the joining direction, the pillar being used to pass through a through hole of the circuit board;
an elastic element, disposed between the sliding block and one side plate of the base, the sliding block sliding towards the joining direction to deform the elastic element elastically; and
a stopper, disposed on the case to be against one side edge of the circuit board and restrict the movement of the circuit board.

2. The positioning structure as claimed in claim 1, wherein the elastic element is a compression spring.

3. The positioning structure as claimed in claim 1, wherein the elastic element is an extension spring.

4. The positioning structure as claimed in claim 1, wherein the elastic element comprises a compression spring and an extension spring respectively disposed on two opposite sides of the sliding block.

5. The positioning structure as claimed in claim 1, wherein the stopper is a rotating stopper pivoted on the case to rotate horizontally relative to the case.

6. The positioning structure as claimed in claim 1, wherein the base is a hollow housing.
